(19) United States
(12) Patent Application Publication
(10) Pub. No.: US 2025/0261401 A1
(43) Pub. Date: Aug. 14, 2025

(54) SEMICONDUCTOR DEVICE

(71) Applicant: FUJI ELECTRIC CO., LTD., Kawasaki-shi (JP)

(72) Inventor: Syunki NARITA, Matsumoto-city (JP)

(73) Assignee: FUJI ELECTRIC CO., LTD., Kawasaki-shi (JP)

(21) Appl. No.: 19/005,892

(22) Filed: Dec. 30, 2024

(30) Foreign Application Priority Data
Feb. 8, 2024 (JP) 2024-018215

(51) Int. Cl. H10D 30/66; H10D 62/832

(52) U.S. Cl. CPC H10D 30/665; H10D 30/668; H10D 62/8325

(57) ABSTRACT

A semiconductor device includes a semiconductor substrate of a first conductivity type, having an active region, a termination region, and a transition region, first semiconductor regions of a second conductivity type in the active region, second semiconductor regions in the active region and the transition region, respectively directly adjacent to a respective one of the first semiconductor regions in the active region, a front electrode connected to the first semiconductor regions, and a source ring having a source ring connection portion that is electrically connected to the front electrode in the transition region, for drawing out a current in the transition region to the front electrode. The source ring connection portion is continuous from the active region to cover the transition region entirely, and has a same width as a width of the transition region in a direction from the active region to the terminal region.

### CROSS REFERENCE TO RELATED APPLICATIONS

This application is based upon and claims the benefit of priority of the prior Japanese Patent Application No. 2024-018215, filed on Feb. 8, 2024, the entire contents of which are incorporated herein by reference.

### BACKGROUND OF THE INVENTION

### 1. Field of the Invention

Embodiments of the disclosure relate to a semiconductor device.

### 2. Description of the Related Art

In a known semiconductor device, a first well region formed in a drift layer at a top surface of the drift layer; a gate electrode; a second well region bordering the first well region in a plan view; an interlayer insulating film; and a gate portion that covers the gate electrode exposed from the interlayer insulating film are provided to reduce adverse effects on a surface electrode of the semiconductor device; and an outer end of the gate electrode is farther from the first well region than is an outer end of the gate portion but closer to the first well region than is an outer end of the second well region (for example, refer to International Publication No. WO 2021/245992).

### SUMMARY OF THE INVENTION

According to an embodiment of the present disclosure, a semiconductor device includes: a semiconductor substrate of a first conductivity type, the semiconductor substrate having an active region through which a main current flows, a termination region surrounding a periphery of the active region, and a transition region between the active region and the termination region; a plurality of first semiconductor regions of a second conductivity type, provided in the active region of the semiconductor substrate; a plurality of second semiconductor regions of the first conductivity type, provided in the active region and the transition region of the semiconductor substrate, and being respectively directly adjacent to respective ones of the plurality of first semiconductor regions in the active region; a front electrode connected to the plurality of first semiconductor regions in the active region, at a surface of the semiconductor substrate; and a source ring having a source ring connection portion that is electrically connected to the front electrode in the transition region, for pulling out a current in the transition region to the front electrode, the source ring having a side facing the semiconductor substrate. Each of the plurality of second semiconductor regions is provided at a side of the semiconductor substrate where the source ring is provided, and the source ring connection portion is continuous from the active region to entirely cover a surface of the semiconductor substrate in the transition region. A width of the source ring connection portion is a same width as a width of the transition region in a direction from the active region to the terminal region.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a top view depicting a structure of a silicon carbide semiconductor device according to an embodiment.

FIG. 2 is a top view of the structure of the silicon carbide semiconductor device according to the embodiment.

FIG. 3 is a cross-sectional view depicting the structure of the silicon carbide semiconductor device according to the embodiment along cutting line Y-Y′ depicted in FIG. 1.

FIG. 4 is a cross-sectional view depicting the structure of the silicon carbide semiconductor device according to the embodiment along cutting line X-X′ depicted in FIG. 1.

FIG. 5 is a cross-sectional view of a structure of a conventional silicon carbide semiconductor device along cutting line Y-Y′ depicted in FIG. 7.

FIG. 6 is a cross-sectional view of the structure of the conventional silicon carbide semiconductor device along cutting line X-X′ depicted in FIG. 7.

FIG. 7 is a plan view of the structure of the conventional silicon carbide semiconductor device.

FIG. 8 is a plan view of electrodes of the conventional silicon carbide semiconductor device.

### DETAILED DESCRIPTION OF THE INVENTION

First, problems associated with the conventional techniques are discussed. In a conventional semiconductor device, a problem occurs in that during rated forward surge current (IFSM) testing, current concentrates at a source ring portion and IFSM capability decreases.

An outline of an embodiment of the present disclosure is described. A semiconductor device according to the present disclosure solving the problems described above has the following features. The semiconductor device includes a semiconductor substrate of a first conductivity type, the semiconductor substrate having an active region through which a main current flows, a termination region surrounding a periphery of the active region, and a transition region between the active region and the termination region. The semiconductor device further has a front electrode connected to a plurality of first semiconductor regions of a second conductivity type in the active region, at a front surface of the semiconductor substrate; a plurality of second semiconductor regions of the first conductivity type, provided in the active region and the transition region of the semiconductor substrate, and being respectively directly adjacent to respective ones of the plurality of first semiconductor regions in the active region, and a source ring having a source ring connection portion that is electrically connected to the front electrode in the transition region, for pulling out a current in the transition region to the front electrode, the source ring having a side facing the semiconductor substrate. Each of the plurality of second semiconductor regions is provided at a side of the semiconductor substrate where the source ring is provided; the source ring connection portion is continuous from the active region to entirely cover a surface of the semiconductor substrate in the transition region; and a width of the source ring connection portion is a same width as a width of the transition region in a direction from the active region to the terminal region.

According to the disclosure above, beneath the source ring is the plurality of second semiconductor regions of the first conductivity type, whereby a flow of current from the plurality of first semiconductor regions of the second conductivity type to the source ring is enabled while a flow of current from the source ring to the plurality of first semiconductor regions may be prevented. Thus, even when resistance increases due to increases in temperature during an IFSM test, a flow of current from the source ring to the plurality of first semiconductor regions may be prevented, concentration of current in the source ring connection portion is prevented, and IFSM capability may be improved. Further, the source ring is provided continuous from the active region, over the entire area of the transition region. Thus, even when current flows in the transition region, the current is distributed over the source ring, whereby a flow of current from the source ring to the plurality of first semiconductor regions of the second conductivity type may be prevented.

Further, in the semiconductor device according to the present disclosure, in the disclosure above, the width of the source ring connection portion is wider than a width of the source ring excluding the source ring connection portion.

Further, in the semiconductor device according to the present disclosure, in the disclosure above, one of the plurality of second semiconductor regions is provided in the transition region, extends to entirely cover the transition region, and further extends to be provided at a portion of the termination region.

Further, in the semiconductor device according to the present disclosure, in the disclosure above, a dopant concentration of the plurality of first semiconductor regions is higher than a dopant concentration of the plurality of second semiconductor regions.

Findings underlying the present disclosure are discussed. First, problems associated with the conventional semiconductor device are discussed. In terms of power semiconductor devices, semiconductor materials to replace silicon are being investigated, and silicon carbide (SiC) is attracting attention as a semiconductor material that enables fabrication (manufacturing) of next-generation power semiconductor devices that have excellent low on-voltage, high-speed characteristics, and high-temperature characteristics.

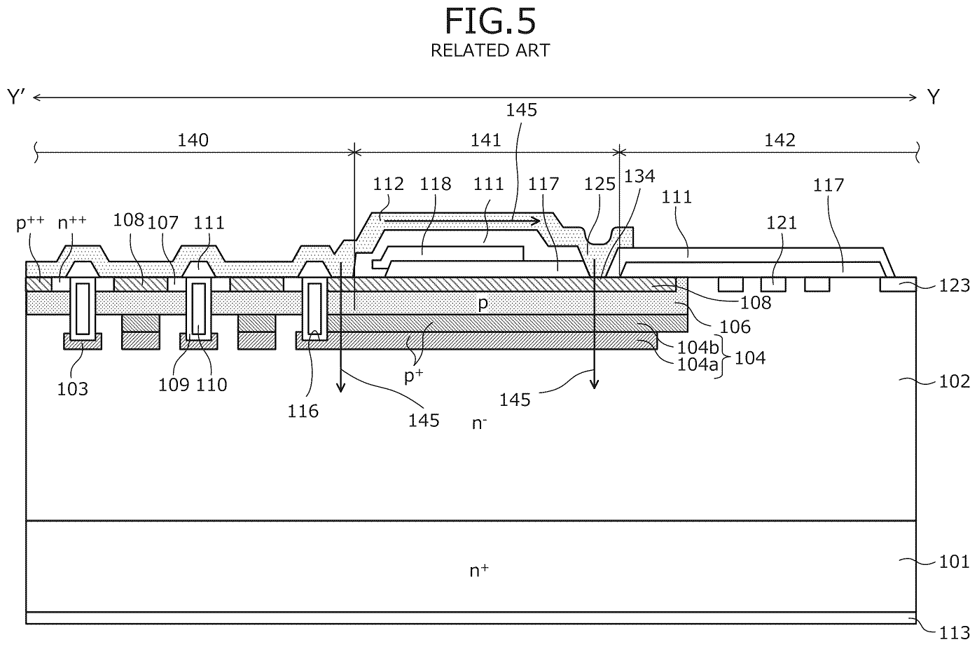

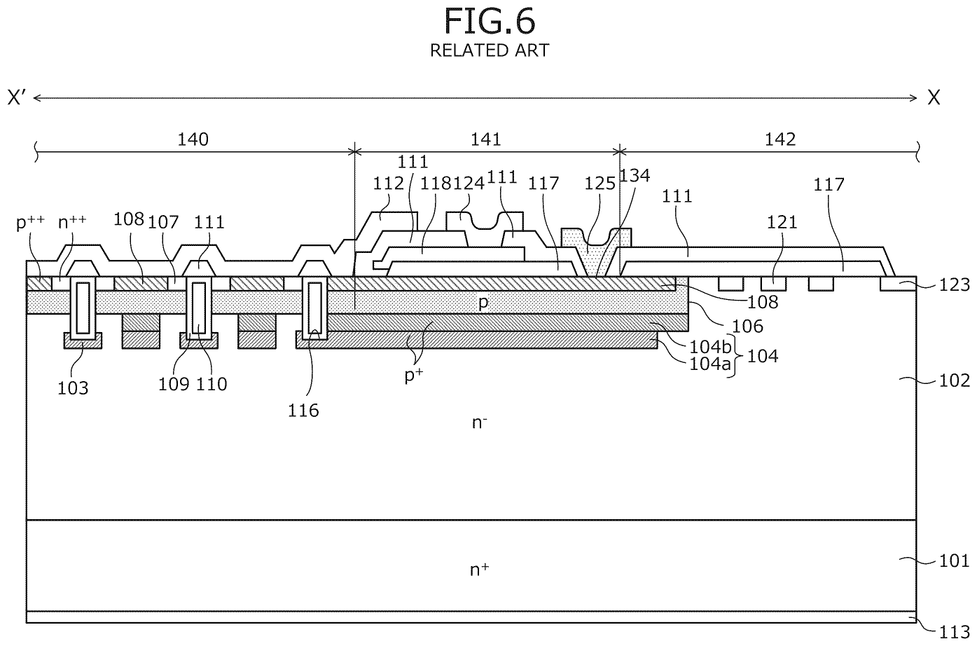

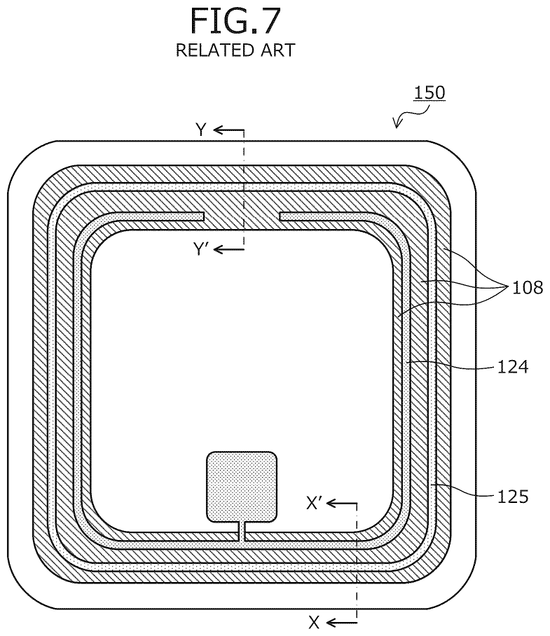

FIGS. 5 and 6 are cross-sectional views depicting a structure of a conventional silicon carbide semiconductor device. FIG. 5 is a cross-sectional view along cutting line Y-Y′ depicted in FIG. 7 while FIG. 6 is a cross-sectional view along cutting line X-X′ depicted in FIG. 7. In FIGS. 5 and 6, a trench-type MOSFET 150 is depicted as the conventional silicon carbide semiconductor device.

As depicted in FIGS. 5 and 6, the trench-type MOSFET 150 has a MOS gate with a general trench gate structure provided in an active region 140 of a semiconductor substrate that contains silicon carbide (hereinafter, silicon carbide substrate), the MOS gate being provided in the semiconductor substrate, at a front surface thereof (surface having a later-described p-type base layer 106). The silicon carbide substrate (semiconductor chip) is formed by sequentially growing silicon carbide layers by epitaxy on an n⁺-type starting substrate (hereinafter, n⁺-type silicon carbide substrate) 101 that contains silicon carbide; the silicon carbide layers constitute an n⁻-type drift layer 102 and a p-type base layer 106, respectively. Hereinafter, the n⁺-type starting substrate 101, the n⁻-type drift layer 102, and the p-type base layer 106 are collectively referred to as a silicon carbide semiconductor substrate.

At a front surface (surface facing the n⁻-type drift layer 102) of the n⁺-type starting substrate 101, MOS gate structures configured by the p-type base layer 106, n⁺⁺-type source regions 107, trenches 116, gate insulating films 109, and gate electrodes 110 are provided. Further, reference numerals 108, 111, and 112 are p⁺⁺-type contact regions, an interlayer insulating film, and a source electrode, respectively. A back electrode 113 constituting a drain electrode is provided at a back surface of the n⁺-type starting substrate 101.

In the n⁻-type drift layer 102, at a front surface thereof, second p⁺-type base regions 104 configured by first p⁺-type regions 104a and second p⁺-type regions 104b are selectively provided between the trenches 116. Further, in the n⁻-type drift layer 102, first p⁺-type base regions 103 are selectively provided so as to border an entire bottom of each of the trenches 116.

Further, as depicted in FIGS. 5 and 6, the trench-type MOSFET 150 has the active region 140 through which current flows, when a device structure is formed and is in an on-state; a termination structure region 142 that surrounds a periphery of the active region 140 in a plan view and sustains a breakdown voltage; and a transition region 141 between the active region 140 and the termination structure region 142.

In the termination structure region 142, the p-type base layer 106, the p⁺⁺-type contact regions 108, and the second p⁺-type base regions 104 are partially provided while in a portion of the termination structure region 142 free of the p-type base layer 106, the p⁺⁺-type contact regions 108, and the second p⁺-type base regions 104: the n⁻-type drift layer 102 is exposed and at the surface of the n⁻-type drift layer 102, a voltage withstand structure such as a junction termination extension (JTE) structure, a guard ring structure 121, etc. is provided.

The guard ring structure 121 is constituted by p-type regions that have different dopant concentrations and, in a plan view, have a substantially rectangular shape surrounding the periphery of the active region 140 and are disposed in descending order of dopant concentration in a direction from the active region 140 side (center of the n⁺-type starting substrate 101) to the outside (end of the n⁺-type starting substrate 101). Additionally, closer to the end of the n⁺-type starting substrate 101 than is the voltage withstand structure, an n⁺⁺-type region 123 constituting a channel stopper is disposed. An initial oxide film 117 and the interlayer insulating film 111 are provided at the surfaces of the voltage withstand structure and the n⁺⁺-type region 123, and a protective film (not depicted) containing a polyimide or the like is provided at a surface of the trench-type MOSFET 150.

The energy level of p-type dopants is deep in SiC and thus, resistance in a p-type region is high, especially at low temperatures such as −40 degrees C. or −55 degrees C. Thus, when dV/dt is applied to the device, lateral voltage drop due to hole current flowing in the p-type region is large, and a large voltage is applied between the p-type region and an electrode provided on the p-type region via the insulating film, resulting in a defect in which the insulating film is destroyed. This phenomenon tends to occur in a vicinity of the active region, where current from a non-active region such as the voltage withstand structure concentrates. To solve this problem, a source ring 125 that pulls out the hole current in the vicinity of the active region 140 and flows the hole current through the source electrode 112 is conventionally provided.

As depicted in FIGS. 5 and 6, in the transition region 141, the initial oxide film 117 and the interlayer insulating film 111 are provided at a front surface of the p⁺⁺-type contact region 108 in the transition region 141; the source ring 125 is embedded in openings of the initial oxide film 117 and the interlayer insulating film 111; and a silicide layer 134 of the source ring 125 is in ohmic contact with the p⁺⁺-type contact region 108. The source ring 125 is electrically connected to the source electrode 112. This configuration enables the hole current in the vicinity of the active region to be pulled out by the source ring 125 and flowed through the source electrode 112.

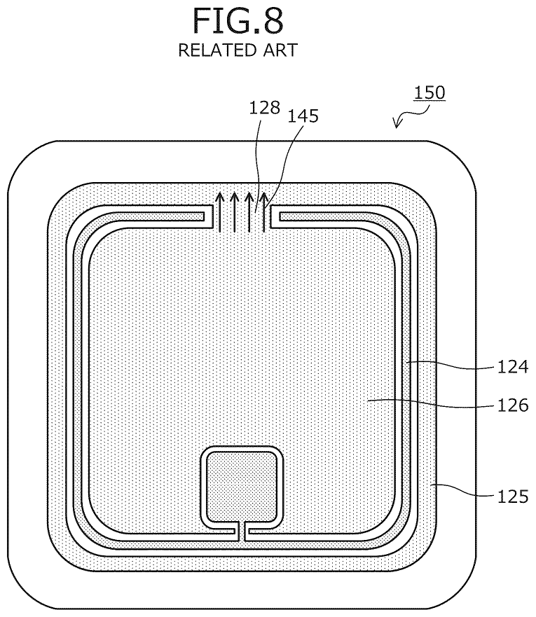

Further, as depicted in FIG. 6, in the transition region 141, a gate ring 124 for connecting the gate electrodes 110 to a gate electrode pad 127 (refer to FIG. 8) is provided. In the transition region 141, to insulate the p⁺⁺-type contact region 108 therein, the initial oxide film 117 is provided and a polysilicon 118 connected to the gate electrodes 110 is provided on the initial oxide film 117. The gate ring 124 is connected to the polysilicon 118 by an opening provided in the interlayer insulating film 111.

FIG. 7 is a plan view depicting the gate ring 124, the source ring 125, and the p⁺⁺-type contact regions 108 of the conventional silicon carbide semiconductor device. As depicted in FIG. 7, one of the p⁺⁺-type contact regions 108 is provided beneath the gate ring 124 and the source ring 125.

FIG. 8 is a plan view of electrodes of the conventional silicon carbide semiconductor device. As depicted in FIG. 8, at a top surface of the trench-type MOSFET 150, a source electrode pad 126 connected to the source electrode 112 (refer to FIG. 5) and a gate electrode pad 127 connected to the gate electrodes 110 (refer to FIG. 5) via the gate ring 124 are provided. The gate ring 124 is formed in a substantially rectangular shape surrounding a periphery of the source electrode pad 126 in a plan view. The source ring 125 is connected to the source electrode 112 at a source ring connection portion 128. The source ring connection portion 128 may be provided in plural.

In silicon carbide semiconductor device in which the source ring 125 is provided, a problem arises in that when resistance increases due to increases in temperature during an IFSM test, a current 145 flows from the source ring 125 to the p⁺⁺-type contact region 108 and, as depicted in FIG. 8, the current 145 concentrates at the source ring connection portion 128 whereby the IFSM capability decreases.

Embodiments of a semiconductor device according to the present disclosure solving the problems of the conventional semiconductor device described above are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments beneath and the accompanying drawings, main portions that are identical are given the same reference numerals and are not repeatedly described. Further, with consideration of variation in manufacturing, description indicating the same or equal may be within 5%.

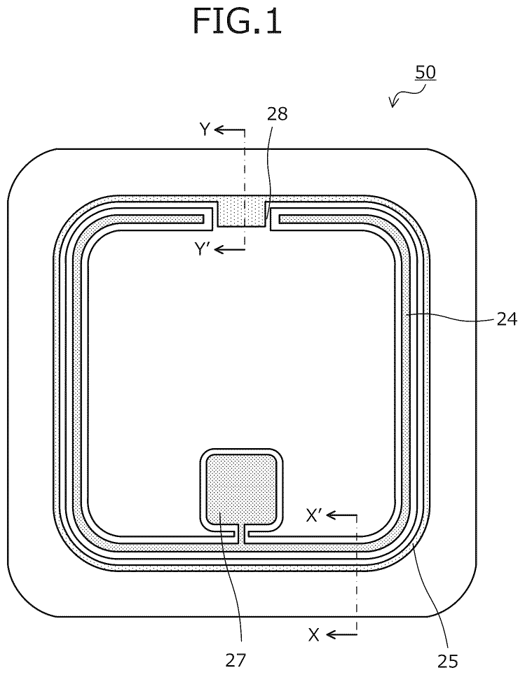

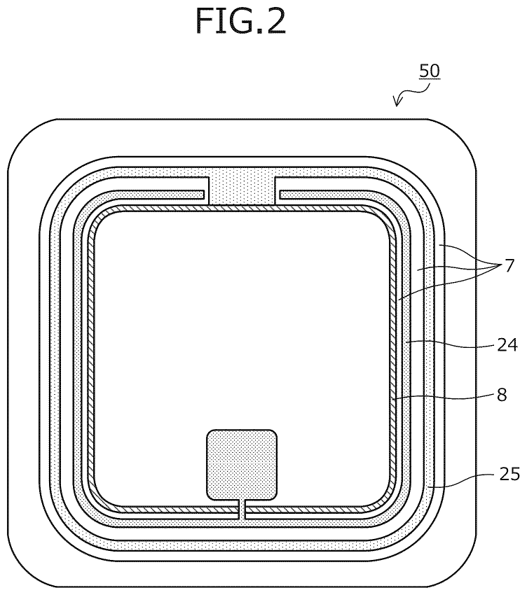

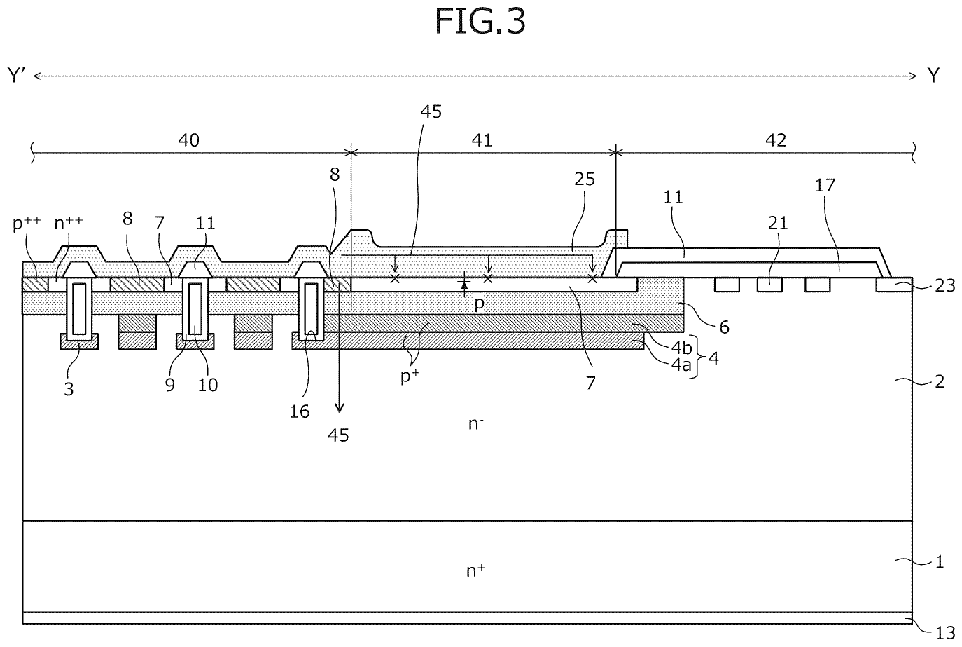

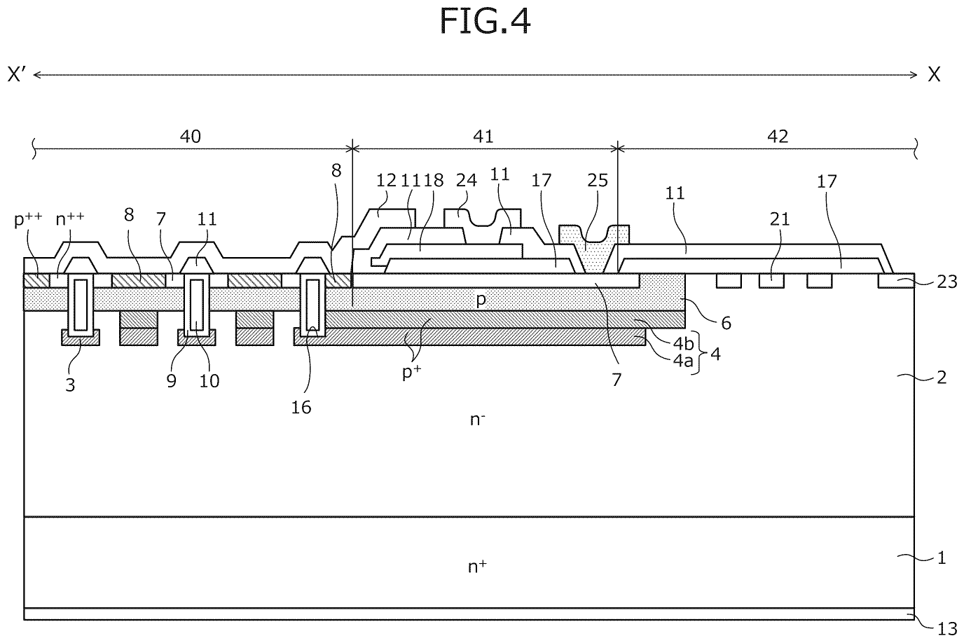

A semiconductor device according to the present disclosure contains a wide band gap semiconductor. In an embodiment, a silicon carbide semiconductor device fabricated (manufactured) using, for example, silicon carbide (SiC) as a wide band gap semiconductor is described taking a trench-type MOSFET 50 as an example. FIG. 1 is a top view depicting a structure of a gate ring 24, a source ring 25, a gate electrode pad 27, and a source ring connection portion 28 of the silicon carbide semiconductor device according to the embodiment. FIG. 2 is a top view of the structure of the gate ring 24, the source ring 25, p⁺⁺-type contact regions 8, and n⁺⁺-type source regions 7 of the silicon carbide semiconductor device according to the embodiment. FIG. 3 is a cross-sectional view depicting the structure of the silicon carbide semiconductor device according to the embodiment along cutting line Y-Y′ depicted in FIG. 1. FIG. 4 is a cross-sectional view depicting the structure of the silicon carbide semiconductor device according to the embodiment along cutting line X-X′ depicted in FIG. 1.

As depicted in FIGS. 1 to 4, the trench-type MOSFET 50 according to the embodiment includes an active region 40 in which a device structure is formed and through which a current flows during an on-state, a termination structure region 42 surrounding a periphery of the active region 40 in a plan view and sustaining a breakdown voltage, and a transition region 41 between the active region 40 and the termination structure region 42. Further, in the trench-type MOSFET 50, an n⁻-type drift layer 2 is deposited on a first main surface (front surface), for example, a (0001) plane, (Si-face), of an n⁺-type starting substrate (semiconductor substrate of a first conductivity type) 1.

The n⁺-type starting substrate 1 is a silicon carbide single crystal substrate. The n⁻-type drift layer 2, for example, is a low-concentration n-type drift layer having a dopant concentration lower than a dopant concentration of the n⁺-type starting substrate 1. At a first surface of the n⁻-type drift layer (semiconductor substrate of the first conductivity type) 2, opposite to a second surface thereof facing the n⁺-type starting substrate 1, an n-type high-concentration region (not depicted) may be provided. The n-type high-concentration region is a high-concentration n-type layer having a dopant concentration lower than the dopant concentration of the n⁺-type starting substrate 1 but higher than the dopant concentration of the n⁻-type drift layer 2.

At the first surface of the n⁻-type drift layer 2 (in an instance in which the n-type high-concentration region is provided, at a first surface of the n-type high-concentration region), a p-type base layer (first semiconductor region of a second conductivity type) 6 is provided. Hereinafter, the n⁺-type starting substrate 1, the n⁻-type drift layer 2, and the p-type base layer 6 are collectively referred to as a silicon carbide semiconductor substrate. In the p-type base layer 6, the n⁺⁺-type source regions (second semiconductor regions of the first conductivity type) 7 and the p⁺⁺-type contact regions (first semiconductor regions of the second conductivity type) 8 are selectively provided.

A back electrode 13 constituting a drain electrode is provided at a second main surface (back surface, i.e., back surface of the silicon carbide semiconductor substrate) of the n⁺-type starting substrate 1.

In the silicon carbide semiconductor substrate, at a first main surface (surface having the p-type base layer 6) thereof, a trench structure is formed. In particular, from a first surface (the first main surface of the silicon carbide semiconductor substrate) of the p-type base layer 6, opposite to a second surface thereof facing the n⁺-type starting substrate 1, trenches 16 penetrate through the p-type base layer 6 and reach the n⁻-type drift layer 2. Further, each of the trenches 16 is provided in a stripe-like shape. Along respective inner walls of the trenches 16, a gate insulating film 9 is formed at bottoms and sidewalls of the trenches 16 and gate electrodes 10 are formed on the gate insulating film 9 in the trenches 16. The gate insulating film 9 insulates the gate electrodes 10 from the n⁻-type drift layer 2 and the p-type base layer 6. A portion of each of the gate electrodes 10 may protrude from a top (side facing a later-described source electrode 12) of each of the trenches 16 in a direction to the source electrode 12.

In the n⁻-type drift layer 2, closer to the first surface (surface facing the first main surface of the silicon carbide semiconductor substrate) thereof than to the second surface thereof facing the n⁺-type starting substrate 1, second p⁺-type base regions (third semiconductor regions of the second conductivity type) 4 are selectively provided. The second p⁺-type base regions 4 are provided in at least a surface layer of the n′-type drift layer 2, at the first surface thereof. The second p⁺-type base regions 4 are apart from the trenches 16 and reach deeper positions closer to the n⁺-type starting substrate 1 than are the bottoms of the trenches 16. The second p⁺-type base regions 4 are configured by first p⁺-type regions 4a of a same thickness as a thickness of first p⁺-type base regions 3 described hereinafter, and second p⁺-type regions 4b provided at surfaces of the first p⁺-type regions 4a., respectively.

The first p⁺-type base regions 3 are provided at positions facing the bottoms of the trenches 16 in a depth direction. A width of each of the first p⁺-type base regions 3 is a same as or wider than a width of each of the trenches 16. The bottoms of the trenches 16 may reach the first p⁺-type base regions 3 or may terminate in the n⁻-type drift layer 2, between the p-type base layer 6 and the first p⁺-type base regions 3. The first p⁺-type base regions 3 and the second p⁺-type base regions 4 are doped with, for example, aluminum (Al).

The first p⁺-type base regions 3 form a structure in which the first p⁺-type base regions 3 are connected to the second p⁺-type base regions 4 by portions of each of the first p⁺-type base regions 3 being extended toward the trenches 16. The first p⁺-type regions 4a of the second p⁺-type base regions 4 are closer to the n⁺-type starting substrate 1 than are the bottoms of the trenches 16 and partially extend to be connected to the first p⁺-type base regions 3. Further, the second p⁺-type regions 4b of the second p⁺-type base regions 4 are closer to the source electrode 12 than are the bottoms of the trenches 16 and may partially extend. FIGS. 2 and 3 depict locations where the first p⁺-type base regions 3 and the second p⁺-type base regions 4 are apart from each other. In portions of the active region 40 and the transition region 41, the p-type base layer 6 is provided so as to cover the second p⁺-type regions 4b and the n⁻-type drift layer 2.

Further, of the trenches 16 of the active region 40, an outermost one closest to the transition region 41 has an outer sidewall facing the transition region 41, the outer sidewall being in contact with one of the p⁺⁺-type contact regions 8, one of the first p⁺-type regions 4a, and one of the second p⁺-type regions 4b; said one of the second p⁺-type regions 4b is in contact with one of the first p⁺-type base regions 3. Thus, this outer sidewall (sidewall facing the transition region 41) of the outermost one of the trenches 16 is not in contact with the n⁻-type drift layer.

An interlayer insulating film 11 is provided in an entire area of the front surface of the silicon carbide substrate, so as to cover the gate electrodes 10 embedded in the trenches 16. The source electrode (front electrode) 12 is in ohmic contact with the n⁺⁺-type source regions 7 and the p⁺⁺-type contact regions 8 via contact holes opened in the interlayer insulating film 11. The source electrode 12 is electrically insulated from the gate electrodes 10 by the interlayer insulating film 11. A source electrode pad (not depicted) is provided on the source electrode 12. The source electrode 12 and the source electrode pad may be a single layer or may be stacked layers of different materials.

In FIGS. 3 and 4, while three trench MOS structures are depicted in the active region 40, further trench MOS (metal-oxide-semiconductor insulated gate) structures may be disposed in parallel.

Further, in the transition region 41, the gate ring 24 for connecting the gate electrodes 10 to a gate electrode pad 27 is formed in a substantially rectangular shape surrounding the periphery of the active region 40 in a plan view. In the transition region 41, an initial oxide film 17 functioning as a field oxide film is provided above the p⁺⁺-type contact region 8 in the transition region 41 to insulate the p⁺⁺-type contact region 8. The gate insulating film 9 is provided on the initial oxide film 17 and a polysilicon 18 connected to the gate electrodes 10 is provided on the gate insulating film 9. The gate ring 24 is connected to the polysilicon 18 by an opening provided in the interlayer insulating film 11.

Further, in the transition region 41, the source ring 25 for pulling out charge is formed in a substantially rectangular shape surrounding a periphery of the gate ring 24 in a plan view. The source ring 25 is connected to the source electrode 12 by the source ring connection portion 28. The source ring connection portion 28 may be provided in plural. The source ring 25 is connected to an outermost one of the n⁺⁺-type source regions 7 by openings provided, respectively, in the interlayer insulating film 11, the gate insulating film 9, and the initial oxide film 17, the outermost one of the n⁺⁺-type source regions 7 being closest to the end of the n⁺-type starting substrate 1, of the n⁺⁺-type source regions 7. As a result, the source ring 25 may lead current generated in the transition region 41 out to the source electrode 12.

Further, the termination structure region 42 is free of the p-type base layer 6 and the n-type high-concentration region; in the termination structure region 42, the n⁻-type drift layer 2 is exposed and a voltage withstand structure such as junction termination extension (JTE) structure, a guard ring structure 21, etc. is provided in the n⁻-type drift layer 2, at the first surface of the n⁻-type drift layer 2.

The guard ring structure 21 is constituted by interspersed p-type regions that progressively reduce the dopant concentration of the guard ring structure 21 in a direction from the transition region 41 to the end of the n⁺-type starting substrate 1, said p-type regions each being disposed in a substantially rectangular shape surrounding the peripheries of the active region 40 and the transition region 41 in a plan view. Further, instead of varying the dopant concentration of said p-type regions, said p-type regions may be disposed so that an interval therebetween is relatively larger the closer said p-type regions are to the end of the n⁺-type starting substrate 1 or said p-type regions may be of different widths and may be disposed in descending order of width in a direction from the transition region 41 to the end of the n⁺-type starting substrate 1. In an instance of a JTE structure, contiguous p-type regions arranged in descending order of dopant concentration in a direction from the transition region 41 to the end of the n⁺-type starting substrate 1 are each disposed in a substantially rectangular shape surrounding the peripheries of the active region 40 and the transition region 41 in a plan view. Closer to the end of the n⁺-type starting substrate 1 than are these voltage withstand structures, an n⁺⁺-type region 23 constituting a channel stopper is disposed. The interlayer insulating film 11, the gate insulating film 9, and the initial oxide film 17 are provided at the surfaces of voltage withstand structures and the n⁺⁺-type region 23, and a protective film (not depicted) constituted by a polyimide or the like is provided at a top surface of the trench-type MOSFET 50.

Here, a boundary between the active region 40 and the transition region 41 is a bottom of steps of the gate insulating film 9 and the interlayer insulating film 11 on the outermost one of the n⁺⁺-type source regions 7 while a boundary between the transition region 41 and the termination structure region 42 is a bottom of a step of the initial oxide film 17.

Further, the n⁺⁺-type source regions 7, the p-type base layer 6, and the second p⁺-type base regions 4 extend to the termination structure region 42, and the voltage withstand structure is provided outside of these regions. The n⁺⁺-type source regions 7 are shorter than the p-type base layer 6, and a portion of the p-type base layer 6 is exposed at the surface of the silicon carbide substrate. In the transition region 41 and the termination structure region 42, in the second p⁺-type base region 4 thereof, the first p⁺-type region 4a is shorter than the second p⁺-type region 4b, which has a same length as a length of a portion of the p-type base layer 6.

In the embodiment, the source ring 25 has a source ring connection portion 28 provided continuously from the active region 40, over an entire portion of the surface of the transition region 41 (cross-sectional view along cutting line Y-Y′); the source ring connection portion 28 of the source ring 25 and the transition region 41 have substantially a same width. The source ring 25 reaches a boundary between the transition region 41 and the termination structure region 42. A portion of the source ring 25 excluding the source ring connection portion 28 (cross-sectional view along cutting line X-X′) and the source ring of the conventional silicon carbide semiconductor device have similar widths.

Further, in the p-type base layer 6, at the first surface thereof, one of the p⁺⁺-type contact regions 8 is provided from the outer sidewall of the outermost one of the trenches 16 to an end of the active region 40. The outermost one of the n⁺⁺-type source regions 7 is in contact with said one of the p⁺⁺-type contact regions 8 and is provided in a portion of the p-type base layer 6, at the first surface of the p-type base layer 6 in the entire area of the transition region 41 and a portion of the termination structure region 42. As a result, the outermost one of the n⁺⁺-type source regions 7 is provided beneath the source ring 25; and the source ring 25 is in contact with the outermost one of the n⁺⁺-type source regions 7 through an opening of the interlayer insulating film 11 but is apart from the p⁺⁺-type contact regions 8.

Further, the n⁺⁺-type source region 7 of the transition region 41 (the outermost one of the n⁺⁺-type source regions 7) may be formed by ion implantation of an n-type dopant in a region beneath the source ring 25 without forming the p⁺⁺-type contact region 8 in the region beneath the source ring 25. Therefore, the dopant concentration of the p⁺⁺-type contact regions 8 is higher than the dopant concentration of the n⁺⁺-type source region 7 of the transition region 41.

In the embodiment, a diode formed by the outermost one of the n⁺⁺-type source regions 7 and the p-type base layer 6 is formed beneath the source ring 25. As a result, a flow of current from the p-type base layer 6 to the source ring 25 is enabled while a flow of current from the source ring 25 to the p-type base layer 6 may be prevented. Thus, even when resistance increases due to increases in temperature during an IFSM test, the flow of a current 45 from the source ring 25 to the p⁺⁺-type contact regions 8 may be prevented, concentration of the current 45 at the source ring connection portion 28 is prevented, and IFSM capability may be improved.

Further, the source ring connection portion 28 of the source ring 25 is provided continuous from the active region 40, over an entire portion of the surface of the transition region 41. As a result, even when the current 45 flows in the transition region 41, the current 45 is distributed over the source ring 25, whereby a flow of current from the source ring 25 to the p-type base layer 6 may be prevented.

Further, similarly to the source ring connection portion 28 (cross-sectional view along cutting line Y-Y′), in the p-type base layer 6, at the first surface of the p-type base layer 6, the outermost one of the n⁺⁺-type source regions 7 is also provided over an entire portion of the transition region 41, other than the portion having the source ring connection portion 28 (cross-sectional view along cutting line X-X′), and extends to a portion of the termination structure region 42. However, configuration may be such that excluding the source ring connection portion 28 (cross-sectional view along cutting line X-X′), the outermost one of the n⁺⁺-type source regions 7 is provided only beneath the source ring 25. In this instance, in the portion of the transition region 41 excluding the portion having the source ring connection portion 28, one of the p⁺⁺-type contact regions 8 is provided from the outer sidewall of the outermost one of trenches 16 and terminates in the transition region 41 and another one of the p⁺⁺-type contact regions 8 is provided in the p-type base layer 6, closer to the end of the n⁺-type starting substrate 1 than is the n⁺⁺-type source region 7 of the transition region 41.

Further, beneath the source ring 25, the n⁺⁺-type source region 7 may be provided to a depth so as to be in contact with the first p⁺-type region 4a. In this instance, a difference of n-type and p-type concentrations (dopant concentration of the n⁺⁺-type source region 7—dopant concentration of the first p⁺-type region 4a) is lower than a difference of the n-type and p-type concentrations (dopant concentration of the n⁺⁺-type source region 7—dopant concentration of the p-type base layer 6) in FIG. 3, whereby imbalance between the n-type and p-type concentrations during reverse bias application may be suppressed.

Here, the source ring connection portion 28 is free of the polysilicon 18. Thus, the guard ring 24 is not continuous and a region apart from the gate electrode pad 27 may be formed. In this region, gate signals are delayed and switching delays occur. However, in an instance of a chip of 3 mm or less, this delay is small enough to be disregarded in normal applications and is not problematic in normal applications.

A method of manufacturing the silicon carbide semiconductor device according to the embodiment may be implemented as follows. Here, an instance of a MOSFET of a 1200V breakdown voltage class being manufactured is described. First, the n⁺-type starting substrate (semiconductor wafer) 1 containing single crystal silicon carbide and doped with an n-type impurity (dopant) such as nitrogen (N) so as to have a dopant concentration of, for example, 2.0×10¹⁹/cm³ is prepared. The front surface of the n⁺-type starting substrate 1 may be, for example, a (0001) plane having an off-angle of about 4 degrees in a <11-20> direction. Next, the n⁻-type drift layer 2 doped with an n-type dopant such as nitrogen to have a dopant concentration of, for example, 1.0×10¹⁶/cm³, is grown by epitaxy on the front surface of the n⁺-type starting substrate 1 to a thickness of, for example, 10 μm.

Next, in the n⁻-type drift layer 2, at the surface thereof, the n-type high-concentration region may be selectively formed by photolithography and ion implantation. In this ion implantation, an n-type impurity (dopant) such as nitrogen may be implanted so as to have a concentration of, for example, 1×10¹⁷/cm³.

Next, the first p⁺-type base regions 3 and the first p⁺-type regions 4a are selectively formed in the n⁻-type drift layer 2 by photolithography and ion implantation. Next, in the n⁻-type drift layer 2, at the surface thereof, the second p⁺-type regions 4b are selectively formed. In this ion implantation, for example, a p-type impurity (dopant) such as aluminum (Al) may be ion implanted in the first p⁺-type base regions 3, the first p⁺-type regions 4a, and the second p⁺-type regions 4b so that a dopant concentration thereof is 5.0×10¹⁸/cm³.

Next, at the surface of the n⁻-type drift layer 2, the p-type base layer 6 doped with a p-type dopant such as aluminum to have a dopant concentration of, for example, 2.0×10¹⁷/cm³ is grown by epitaxy to have a thickness of, for example, 1.3 μm.

By the processes up to here, the silicon carbide substrate in which the n⁻-type drift layer 2 and the p-type base layer 6 are sequentially stacked on the front surface of the n⁺-type starting substrate 1 is fabricated. Next, a process including: formation of an ion implantation mask by photolithography and etching, ion implantation using the ion implantation mask, and removal of the ion implantation mask, as one set is repeatedly performed under different ion implantation conditions, thereby forming in the p-type base layer 6, at the surface thereof, the n⁺⁺-type source regions 7 and the p⁺⁺-type contact regions 8. Preferably, a dopant concentration of the p⁺⁺-type contact regions 8 may be 1.0×10²⁰/cm³.

Further, in the transition region 41 and the termination structure region 42, the n⁺⁺-type source region 7 therein may be formed by ion implantation of an n-type dopant in a region beneath the source ring 25 without forming the p⁺⁺-type contact regions 8 in the region beneath the source ring 25. Therefore, the dopant concentration of the p⁺⁺-type contact regions 8 is higher than the dopant concentration of the n⁺⁺-type source regions 7 of the transition region 41 and the termination structure region 42.

Next, the guard ring structure 21 is selectively formed in the termination structure region 42 by photolithography and ion implantation. Next, the n⁺⁺-type region 23 is selectively formed in the termination structure region 42 by photolithography and ion implantation.

Next, a heat treatment (annealing) is performed thereby activating, for example, the first p⁺-type base regions 3, the n⁺⁺-type source regions 7, the p⁺⁺-type contact regions 8, the guard ring structure 21, and the n⁺⁺-type region 23. A temperature of the heat treatment may be, for example, about 1700 degrees C. A period of the heat treatment may be, for example, about 2 minutes. The ion implanted regions may be activated by a single session of the heat treatment as described or the heat treatment may be performed each time ion implantation is performed.

Next, an oxide film is formed on the surface the p-type base layer 6 (i.e., surfaces of the n⁺⁺-type source regions 7 and surfaces of the p⁺⁺-type contact regions 8). The oxide film may be, for example, a thermal oxide film or a deposited film. The oxide film is formed so that a portion of the oxide film in the active region 40 has a thickness that is thinner than a thickness of a portion of the oxide film formed along an outer periphery of the termination structure region 42.

Next, a resist mask (not depicted) having predetermined openings is formed by photolithography at the surface of the oxide film. Next, openings are formed in the oxide film by dry etching using the resist mask as a mask. Next, the resist mask is removed and the trenches 16 that penetrate through the n⁺⁺-type source regions 7 and the p-type base layer 6 and reach the n⁻-type drift layer 2 are formed by anisotropic dry etching using the oxide film as a mask. The bottoms of the trenches 16 reach the first p⁺-type base regions 3.

Next, isotropic etching and sacrificial oxidation are performed without removing the oxide film. This process removes damage of the trenches 16 and rounds the bottoms of the trenches 16. A sequence in which the isotropic etching and the sacrificial oxidation are performed is interchangeable. Further, either the isotropic etching or the sacrificial oxidation alone may be performed. Thereafter, the portion of the oxide film used as a mask to form the trenches 16 (the portion where the thickness is relatively thin) is removed. At this time, the portion of the oxide film where the thickness is relatively thin and the sacrificial oxide film may be removed concurrently. The oxide film includes the portion that is relatively thin and in the termination structure region 42, the portion that is relatively thick and thus, etching for removing the relatively thin portion of the oxide film is performed in an entire area of the surface, leaving the relatively thick portion of the oxide film in the termination structure region 4. The sacrificial oxide film (not depicted) may be removed together with the relatively thin portion of the oxide film. Further, the oxide film may be removed by photolithography and etching, leaving the oxide film in the termination structure region 42. The oxide film (the relatively thick portion of the oxide film) left in the termination structure region 42 constitutes the initial oxide film 17.

Next, the gate insulating film 9 is formed along surfaces of the initial oxide film 17, the n⁺⁺-type source regions 7, the p⁺⁺-type contact regions 8, and the bottoms and sidewalls of the trenches 16. The gate insulating film 9 may be formed by thermal oxidation of a temperature of about 1000 degrees C. under an atmosphere containing oxygen. Further, the gate insulating film 9 may be formed by a deposition method by a chemical reaction such as that for a high temperature oxide (HTO).

Next, a polycrystalline silicon layer doped with, for example, phosphorus atoms (P) is formed on the gate insulating film 9. The polycrystalline silicon layer is formed so as to be embedded in the trenches 16. The polycrystalline silicon layer is patterned and left inside the trenches 16, thereby forming the gate electrodes 10. A portion of each of the gate electrodes 10 may protrude from a top of each of the trenches 16 in a direction toward the source electrode 12.

Next, for example, a phosphosilicate glass (PSG) is deposited to a thickness of about 1 μm so as to cover the gate insulating film 9 and the gate electrodes 10, thereby forming the interlayer insulating film 11. The interlayer insulating film 11 and the gate insulating film 9 are patterned and selectively removed, thereby forming contact holes and exposing the n⁺⁺-type source regions 7 and the p⁺⁺-type contact regions 8. Thereafter, a heat treatment (reflow) is performed, thereby flattening the interlayer insulating film 11.

Next, a conductive film constituting the source electrode 12 is formed in the contact holes and on the interlayer insulating film 11. The conductive film is selectively removed and, for example, the source electrode 12 is left only in the contact holes. The source electrode 12 is formed so as to be in ohmic contact with the p⁺⁺-type contact regions 8 and the p-type base layer 6.

Next, for example, an aluminum film having a thickness of, for example, about 5 μm is formed by, for example, by a sputtering method, so as to cover the source electrode 12 and the interlayer insulating film 11. Thereafter, the aluminum film is selectively removed and left so as to cover the active region 40 and the transition region 41 of the device overall, thereby forming the gate ring 24, the source ring 25, the source electrode pad 26, and the gate electrode pad 27. The source ring connection portion 28 of the source ring 25 is continuous from the active region 40 and formed over an entire portion of the surface of the transition region 41. Thereafter, as a surface passivation film, a protective film (not depicted) is formed by applying a polyimide, for example, by spin coating, patterning the polyimide using a lithographic method, and performing a heat treatment (curing) on the polyimide. The source electrode pad 26 may be a portion of the source electrode 12 opened (exposed) from the polyimide or may formed by depositing another metal such as nickel on the portion of the source electrode 12 opened (exposed) from the polyimide.

Next, the back electrode 13 constituted by, for example, a nickel (Ni) film, is formed at the back surface (the back surface of the n⁺-type starting substrate 1) of the silicon carbide substrate. Thereafter, for example, a heat treatment is performed at a temperature of about 970 degrees C., whereby the n⁺-type starting substrate 1 and the back electrode 13 become in ohmic contact with each other.

The back electrode 13, for example, may be a stacked film including, sequentially, a titanium (Ti) film, a nickel (Ni) film, and a gold (Au) film or may be a stacked film including a nickel (Ni) film, a titanium (Ti) film, a molybdenum (Mo) film, and a gold (Au) film. Thus, as described, the semiconductor device depicted in FIGS. 1 to 3 is completed.

As described, according to the embodiment, the n⁺⁺-type source regions are beneath each of the source rings, whereby a flow of current from the p-type base layer to the source rings is enabled while a flow of current from the source rings to the p-type base layer is prevented. Thus, even when resistance increases due to increases in temperature during an IFSM test, a flow of current from the source ring to the p⁺⁺-type contact regions may be prevented, concentration of the current at the source ring connection portion is prevented, and IFSM capability may be improved. Further, the source ring connection portion of the source ring is provided continuous from the active region, over an entire portion of the surface of the transition region. As a result, even when current flows in the transition region, the current is distributed over the source ring connection portion of the source ring, whereby the flow of current from the source ring to the p-type base layer may be prevented.

In the foregoing, while an instance in which MOS gate structures are configured at the first main surface of a silicon carbide substrate is described as an example, the present disclosure is not limited hereto and various modifications such as surface orientation of the substrate, etc. are possible. Further, in the embodiments of the present disclosure, while a trench-type MOSFET is described as an example, without limitation hereto, the present disclosure is applicable to various semiconductor devices of various types of configurations such as MOS semiconductor devices like trench-type IGBTs. Further, in the present disclosure, while the first conductivity type is assumed to be an n-type and the second conductivity type is assumed to be a p-type in the embodiments, the present disclosure is similarly implemented when the first conductivity type is a p-type and the second conductivity type is an n-type.

According to the disclosure described above, beneath the source ring is a second semiconductor region of the first conductivity type and thus, a flow of current from a plurality of first semiconductor regions of the second conductivity type to the source ring is enabled while a flow of current from the source ring to the plurality of first semiconductor regions may be prevented. Thus, even when resistance increases due to increases in temperature during an IFSM test, the flow of a current from the source ring to the plurality of first semiconductor regions may be prevented, concentration of the current at source ring connection portion is prevented, and IFSM capability may be improved. Further, the source ring connection portion of the source ring is provided continuous from the active region, over an entire portion of the surface of the transition region. As a result, even when current flows in the transition region, the current is distributed over the source ring connection portion of the source ring, whereby the flow of current from the source ring to the first semiconductor region of the second conductivity type may be prevented.

The semiconductor device according to the present disclosure achieves an effect in that concentration of current in the source ring portion is suppressed and IFSM capability is improved.

As described, the semiconductor device according to the present disclosure is useful for high-voltage semiconductor devices used in power converting equipment, power source devices of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate of a first conductivity type, the semiconductor substrate having an active region through which a main current flows, a termination region surrounding a periphery of the active region, and a transition region between the active region and the termination region;
a plurality of first semiconductor regions of a second conductivity type, provided in the active region of the semiconductor substrate;
a plurality of second semiconductor regions of the first conductivity type, provided in the active region and the transition region of the semiconductor substrate, and being respectively directly adjacent to respective ones of the plurality of first semiconductor regions in the active region;
a front electrode connected to the plurality of first semiconductor regions in the active region, at a surface of the semiconductor substrate; and
a source ring having a source ring connection portion that is electrically connected to the front electrode in the transition region, for pulling out a current in the transition region to the front electrode, the source ring having a side facing the semiconductor substrate, wherein
each of the plurality of second semiconductor regions is provided at a side of the semiconductor substrate where the source ring is provided, and
the source ring connection portion is continuous from the active region to entirely cover a surface of the semiconductor substrate in the transition region, and
a width of the source ring connection portion is a same width as a width of the transition region in a direction from the active region to the terminal region.

2. The semiconductor device according to claim 1, wherein the width of the source ring connection portion is wider than a width of the source ring outside of the source ring connection portion.

3. The semiconductor device according to claim 1, wherein one of the plurality of second semiconductor regions, which is provided in the transition region, extends to entirely cover the transition region and further extends to be provided at a portion of the termination region.

4. The semiconductor device according to claim 1, wherein a dopant concentration of the plurality of first semiconductor regions is higher than a dopant concentration of the plurality of second semiconductor regions.
